(19) United States
(12) Patent Application Publication
(10) Pub. No.: US 2025/0318138 A1
(43) Pub. Date: Oct. 9, 2025

(54) SEMICONDUCTOR MEMORY DEVICE

(71) Applicant: SK hynix Inc., Icheon-si Gyeonggi-do (KR)

(72) Inventors: Won Tae KOO, Icheon-si Gyeonggi-do (KR); Dong Ik SUH, Icheon-si Gyeonggi-do (KR)

(73) Assignee: SK hynix Inc., Icheon-si Gyeonggi-do (KR)

(21) Appl. No.: 18/891,864

(22) Filed: Sep. 20, 2024

(30) Foreign Application Priority Data
Apr. 3, 2024 (KR) 10-2024-0045306

(51) Int. Cl. H10B 51/30; H10B 51/20

(52) U.S. Cl. CPC H10B 51/30; H10B 51/20

(57) ABSTRACT

A semiconductor memory device includes a data storage layer, a word line overlapping with the data storage layer, and a blocking insulating layer interposed between the data storage layer and the word line and including a superlattice structure.

### CROSS-REFERENCE TO RELATED APPLICATION

The present application claims priority under 35 U.S.C. § 119 (a) to Korean patent application number 10-2024-0045306 filed on Apr. 3, 2024, in the Korean Intellectual Property Office, the entire disclosure of which application is incorporated herein by reference.

### BACKGROUND

### 1. Technical Field

Various embodiments of the present disclosure generally relate to an electronic device, and more particularly, to a semiconductor memory device.

### 2. Related Art

A semiconductor memory device is applied not only to small-sized electronic devices but also to electronic devices in various fields such as automobiles, medical care, and data centers. Accordingly, there is an increasing demand for semiconductor memory devices.

A semiconductor memory device includes a plurality of memory cells for storing data. In order to increase the degree of integration of the semiconductor memory device, the size of the memory cells may be reduced or the plurality of memory cells may be stacked over a substrate. The operational reliability of the semiconductor memory device may deteriorate as the size of the memory cell decreases and the number of memory cells increases.

### SUMMARY

According to an embodiment, a semiconductor memory device may include a data storage layer, a word line overlapping with the data storage layer, and a blocking insulating layer interposed between the data storage layer and the word line and including a superlattice structure.

According to an embodiment, a semiconductor memory device may include a plurality of word lines stacked separately from each other, a channel layer extending in a stacking direction of the plurality of word lines to penetrate the plurality of word lines, a blocking insulating layer interposed between the channel layer and each of the plurality of word lines, wherein the blocking insulating layer includes a superlattice structure, a data storage layer interposed between the channel layer and the blocking insulating layer, and a tunnel insulating layer interposed between the channel layer and the data storage layer.

### BRIEF DESCRIPTION OF THE DRAWINGS

FIG. 1 is a circuit diagram illustrating a semiconductor memory device according to an embodiment of the present disclosure;

FIG. 2A is a cross-sectional view illustrating a structure of a memory cell according to an embodiment of the present disclosure and FIG. 2B is an enlarged view of a blocking insulating layer shown in FIG. 2A;

FIG. 3A is a perspective view illustrating a three-dimensional memory cell array of a semiconductor memory device according to an embodiment of the present disclosure and FIG. 3B is a cross-sectional view taken along a word line shown in FIG. 3A;

FIG. 4 is a graph for illustrating charge-voltage characteristics of a blocking insulating layer according to an embodiment of the present disclosure;

FIGS. 5 and 6 are diagrams illustrating an erase operation of a semiconductor memory device according to an embodiment of the present disclosure;

FIG. 7 is a graph for illustrating current-voltage characteristics of a program state and an erase state on memory cells according to an embodiment of the present disclosure;

FIGS. 8A and 8B are cross-sectional views illustrating a superlattice structure according to embodiments of the present disclosure; and

FIG. 9 is a block diagram illustrating an electronic system according to an embodiment of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Hereinafter, terms such as ‘first’ and ‘second,’ used to describe various components, are employed for the purpose of distinguishing one component from another component, and the order or number of the components is not limited by the terms.

Further, a component represented in a singular form or a plural form is not construed as limiting the number of components as long as it is not specifically mentioned in a sentence.

Various embodiments are directed to a semiconductor memory device capable of improving the operational reliability.

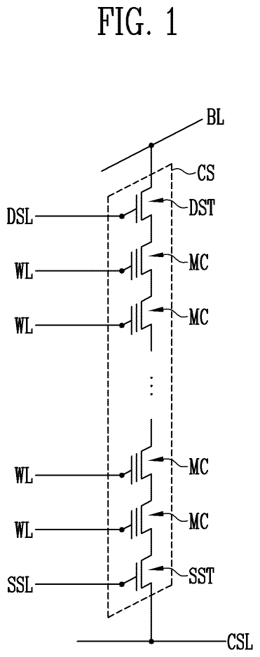

FIG. 1 is a circuit diagram illustrating a semiconductor memory device according to an embodiment of the present disclosure.

The semiconductor memory device may include a plurality of memory blocks, and each of the memory blocks may include a plurality of memory cell strings CS that are coupled to a common source line CSL and a plurality of bit lines BL.

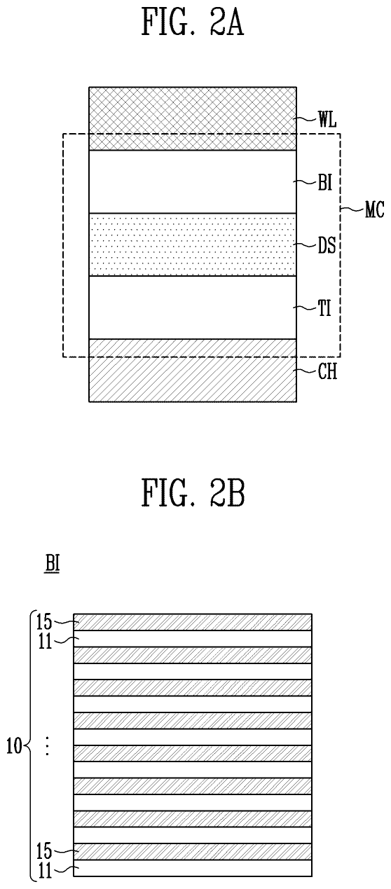

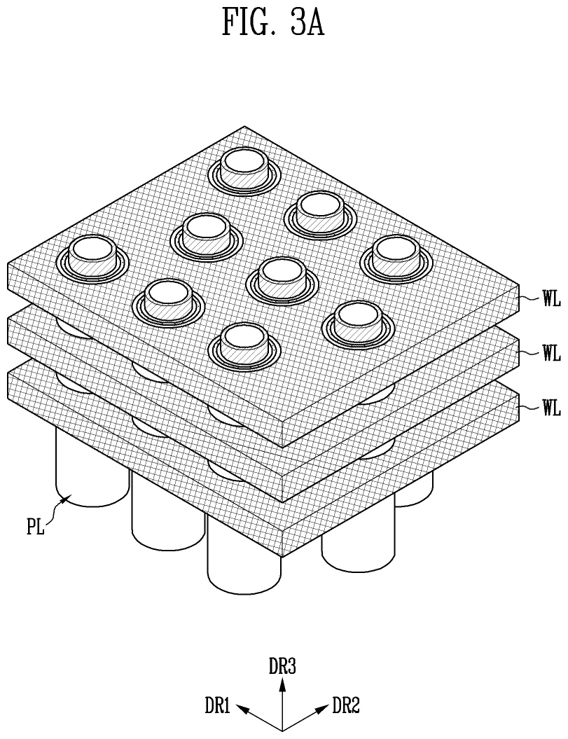

Referring to FIG. 1, each of the memory cell strings CS may be connected to the common source line CSL and a corresponding one of the bit lines BL. The memory cell string CS may include at least one source select transistor SST, a plurality of memory cells MC, and at least one drain select transistor DST coupled in series by a channel layer (a channel layer CH shown in FIG. 2A or 3A). The plurality of memory cells MC may be electrically coupled to the common source line CSL via the source select transistors SST. The plurality of memory cells MC may be electrically coupled to the bit line BL via the drain select transistor DST.

The common source line CSL and the bit line BL may be electrically coupled to a channel layer of the memory cell string CS.

A source select line SSL may serve as a gate electrode of the source select transistor SST, a plurality of word lines WL may serve as a plurality of gate electrodes of the plurality of memory cells MC, and a drain select line DSL may serve as a gate electrode of the drain select transistor DST. The source select line SSL, the plurality of word lines WL, and the drain select line DSL may overlap the channel layer of the memory cell string CS.

In an embodiment, in a two-dimensional semiconductor memory device, the source select line SSL, the plurality of word lines WL, and the drain select line DSL may be disposed over an active region of a semiconductor substrate which is provided as a channel layer. Though not shown, the source select line SSL, the plurality of word lines WL, and the drain select line DSL may extend next to each other, and the active region may extend in a direction crossing the source select line SSL, the plurality of word lines WL, and the drain select line DSL. Each of the common source line CSL and the bit line BL may be electrically coupled to the active region via a conductive contact corresponding thereto. A conductive contact that is coupled to the common source line CSL may contact a portion of the active region adjacent to the source select line SSL and a conductive contact that is coupled to the bit line BL may contact a portion of the active region adjacent to the drain select line DSL.

In an embodiment, in a three-dimensional semiconductor memory device, the source select line SSL, the plurality of word lines WL, and the drain select line DSL may be disposed at different distances from the common source line CSL along a side portion of the channel layer extending from the common source line CSL towards the bit line BL. The plurality of word lines WL may be disposed between the source select line SSL and the drain select line DSL.

Each of the memory cells MC may be a non-volatile memory cell. In an embodiment, the memory cell MC may be a NAND flash memory cell.

During a program operation, in a state where a power supply voltage is applied to a selected drain select line and a ground voltage is applied to a selected bit line, a program voltage may be applied to a selected word line. The program voltage may be a high voltage. The potential of the channel layer of the selected memory string may be set to a ground voltage level. In addition, a selected memory cell may be programmed due to the potential difference between the selected word line and the channel layer of the selected memory cell string.

During an erase operation, in a state where an erase voltage, which is applied to the common source line CSL, is applied to a channel layer of a memory cell string of a selected memory block and a ground voltage is applied to the drain select line DSL, a word line voltage may be applied to the plurality of word lines WL. The erase voltage may be a high voltage and the word line voltage may be a low voltage, such as a ground voltage. The plurality of memory cells MC may be erased due to the potential difference between the channel layer of the memory cell string and the plurality of word lines WL.

The memory cell MC may be a single-level cell that stores single-bit data or a multi-level cell that stores two or more bits of multi-bit data. The single-level cell may have any one of an erase state and a program state according to a threshold voltage of the memory cell MC. The multi-level cell may have any one of an erase state and a plurality of program states according to the threshold voltage.

FIG. 2A is a cross-sectional view illustrating a structure of the memory cell MC according to an embodiment of the present disclosure. FIG. 2B is an enlarged view of a blocking insulating layer BI shown in FIG. 2A.

Referring to FIG. 2A, the memory cell MC may include the blocking insulating layer BI interposed between the word line WL and the channel layer CH, a data storage layer DS interposed between the channel layer CH and the blocking insulating layer BI, and a tunnel insulating layer TI interposed between the channel layer CH and the data storage layer DS.

The data storage layer DS may include a material having a smaller energy band gap than the tunnel insulating layer TI and the blocking insulating layer BI. In an embodiment, the data storage layer DS may be a charge trap layer including a silicon nitride layer.

The tunnel insulating layer TI may include a material selected from materials having a greater energy band gap than the data storage layer DS. In an embodiment, the tunnel insulating layer TI may include a silicon oxide (SiO₂) layer, a silicon oxynitride layer (SiON), or the like.

The blocking insulating layer BI may have a greater energy band gap than the data storage layer DS and may include a material selected from materials having a higher dielectric constant than the tunnel insulating layer TI. The blocking insulating layer BI may have a superlattice structure 10.

Referring to FIG. 2B, the superlattice structure 10 of the blocking insulating layer BI may include one or more pairs of a first dielectric layer 11 and a second dielectric layer 15. The first dielectric layer 11 and the second dielectric layer 15 may be alternately disposed in a direction from the data storage layer DS towards the word line WL shown in FIG. 2A.

The first dielectric layer 11 and the second dielectric layer 15 may include a crystalline oxide formed through hetero-epitaxial growth. In an embodiment, the crystalline oxide may include a crystalline metal oxide. The first dielectric layer 11 and the second dielectric layer 15 may include a material selected from a material group that may cause strain at the interfaces therebetween by reducing or preventing atoms in the first dielectric layer 11 or the second dielectric layer 15 from diffusing into the interfaces. In addition, one of the first dielectric layer 11 and the second dielectric layer 15 may include a ferroelectric material and the other may include an antiferroelectric material. In an embodiment, the first dielectric layer 11 and the second dielectric layer 15 may include different crystalline phases or different crystalline phase distributions. The ferroelectric material may include an orthorhombic crystalline phase. Alternatively, the ferroelectric material may include an orthorhombic crystalline phase, a tetragonal crystalline phase, and a monoclinic crystalline phase, and the orthorhombic phase may be present in greater quantity than the other phases. The antiferroelectric material may include a tetragonal crystalline phase. Alternatively, the antiferroelectric material may include an orthorhombic crystalline phase, a tetragonal crystalline phase, and a monoclinic crystalline phase, and the tetragonal phase may be present in greater quantity than the other phases.

The polarizability of the superlattice structure 10 may increase due to strain in the superlattice structure 10. Accordingly, in an embodiment, a dielectric constant of the blocking insulating layer BI having the superlattice structure 10 may be greater than that of a blocking insulating layer including a silicon oxide layer or a blocking insulating layer including different kinds of paraelectric layers (for example, a paraelectric aluminum oxide layer and a paraelectric hafnium oxide layer).

In an embodiment, one of the first dielectric layer 11 and the second dielectric layer 15 having the superlattice structure 10 may include a hafnium oxide (HfO₂) layer and the other may include a zirconium oxide (ZrO₂) layer.

In an embodiment, the degree of integration of the semiconductor memory device may be maximized in a three-dimensional semiconductor memory device including the blocking insulating layer BI having the superlattice structure 10. The three-dimensional semiconductor memory device may include a three-dimensional memory cell array. The three-dimensional memory cell array will be described below with references to FIGS. 3A and 3B. Though not shown, the blocking insulating layer BI having the superlattice structure 10 may be applied to a two-dimensional semiconductor memory device. The two-dimensional semiconductor memory device may include an active region defined in a substrate and a plurality of memory cells disposed over the active region in an extending direction of the active region.

FIG. 3A is a perspective view illustrating a three-dimensional memory cell array of a semiconductor memory device according to an embodiment of the present disclosure. FIG. 3B is a cross-sectional view taken along the word line WL shown in FIG. 3A.

Referring to FIG. 3A, the three-dimensional memory cell array may include the plurality of word lines WL and a plurality of pillars PL.

Each of the word lines WL may extend in a first direction DR1 and a second direction DR2. The first direction DR1 and the second direction DR2 may cross each other in an XY plane. The plurality of word lines WL may be stacked separately from each other in a third direction DR3. The third direction DR3 may be a vertical direction orthogonal to the XY plane and may be a Z-axis direction.

The plurality of pillars PL may be disposed in a plurality of holes of each word line WL. The plurality of pillars PL may extend in the third direction DR3 to penetrate the plurality of word lines WL. FIG. 3B shows a cross-section of each pillar PL on a layer in which each of the word lines WL is disposed.

Referring to FIGS. 3A and 3B, the pillar PL may include the channel layer CH, the tunnel insulating layer TI, the data storage layer DS, and the blocking insulating layer BI.

The channel layer CH may include a semiconductor material that may serve as a channel region of the memory cell string CS. In an embodiment, the channel layer CH may include silicon, germanium, or a mixture thereof. The channel layer CH may extend in the third direction DR3 to penetrate the plurality of word lines WL. In an embodiment, the channel layer CH may have a tubular structure in which a central region thereof is filled with an insulating material. However, embodiments of the present disclosure are not limited to the descriptions above and the channel layer CH may be formed to fill a central region of the hole defined in the word line WL. In an embodiment, the word line WL may overlap with the channel layer CH in the first and second directions DR1 and DR2. In an embodiment, the word line WL may overlap with the data storage layer DS in the first and second directions DR1 and DR2. In an embodiment, the word line WL may overlap with the blocking insulating layer BI in the first and second directions DR1 and DR2. In an embodiment, the word line WL may overlap with the tunnel insulating layer TI in the first and second directions DR1 and DR2.

The blocking insulating layer BI may be interposed between the channel layer CH and each of the plurality of word lines WL. The blocking insulating layer BI may extend in the third direction DR3 along a side wall of the channel layer CH or may be cut between adjacent word lines WL in the third direction DR3. The blocking insulating layer BI may include the superlattice structure 10 shown in FIG. 2B, and the first dielectric layer 11 and the second dielectric layer 15 forming the superlattice structure 10 may be alternately disposed in a direction from the data storage layer DS towards the plurality of word lines WL.

The data storage layer DS may be interposed between the channel layer CH and the blocking insulating layer BI. The data storage layer DS may extend between adjacent word lines WL in the third direction DR3 without interruption or may be cut between adjacent word lines WL in the third direction DR3. The data storage layer DS may include the same material as described above with reference to FIG. 2A.

The tunnel insulating layer TI may be interposed between the channel layer CH and the data storage layer DS. The tunnel insulating layer TI may extend in the third direction DR3 between adjacent word lines WL in the third direction DR3 without interruption or may be cut between adjacent word lines WL in the third direction DR3. The tunnel insulating layer TI may include the same material as described above with reference to FIG. 2A.

Each pillar PL may be disposed in each hole that penetrates each of the word lines WL. In order to mitigate an increase of the resistance of the word line WL, the volume of the word line WL may be increased by reducing the diameter of the hole. The thickness of the blocking insulating layer BI constituting the pillar PL in the hole may be decreased accordingly. According to an embodiment of the present disclosure, as the blocking insulating layer BI has the superlattice structure 10, even when the thickness of the blocking insulating layer BI decreases, the blocking insulating layer BI may have a higher dielectric constant than a silicon oxide layer, thereby improving the operational reliability of the semiconductor memory device.

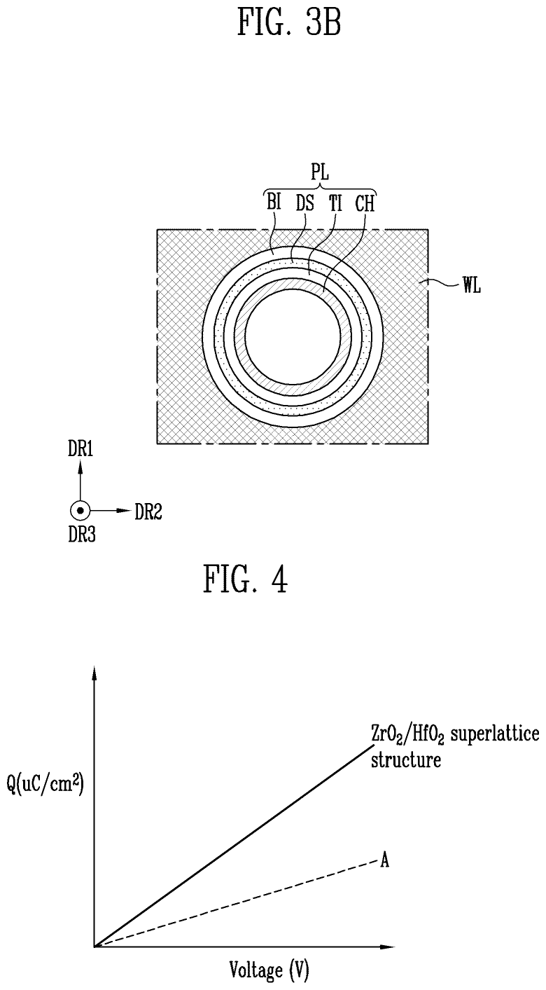

FIG. 4 is a graph for illustrating charge-voltage characteristics of the blocking insulating layer BI according to an embodiment of the present disclosure.

Referring to FIG. 4, the blocking insulating layer BI according to an embodiment of the present disclosure may include a superlattice structure in which ferroelectric zirconium oxide layers and antiferroelectric hafnium oxide layers are repeated periodically. Hereinafter, the superlattice structure is referred to as a “ZrO₂/HfO₂ superlattice structure”. As a control group, a blocking insulating layer may include a single dielectric layer. The single-layered dielectric layer may be a single hafnium oxide (HfO₂) layer or a single zirconium oxide (ZrO₂) layer. Hereinafter, the control group “A” includes the single hafnium oxide (HfO₂) layer.

When a voltage is applied so that an electric field may be applied to each of the ZrO₂/HfO₂ superlattice structure and the control group “A” with the same thickness, each of the ZrO₂/HfO₂ superlattice structure and the control group “A” may be charged with electric charges. A surface charge density Q(uC/cm²) is the amount of electric charge per unit surface area. The charge variation with respect to the voltage variation may correspond to the capacitance and may be approximately proportional to the dielectric constant. According to the graph shown in FIG. 4, the ZrO₂/HfO₂ superlattice structure may have a higher dielectric constant than the control group “A”.

The ZrO₂/HfO₂ superlattice structure having a higher dielectric constant relative to the control group “A” may have a smaller effective oxide thickness than a single silicon oxide (SiO₂) layer, a single hafnium oxide (HfO₂) layer, or a single zirconium oxide (ZrO₂) layer.

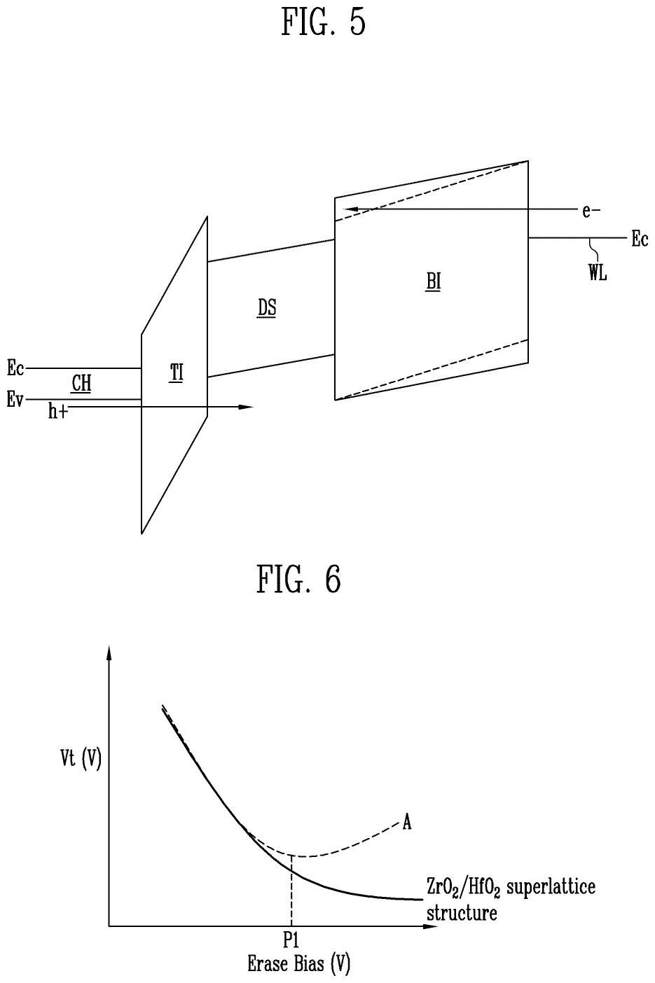

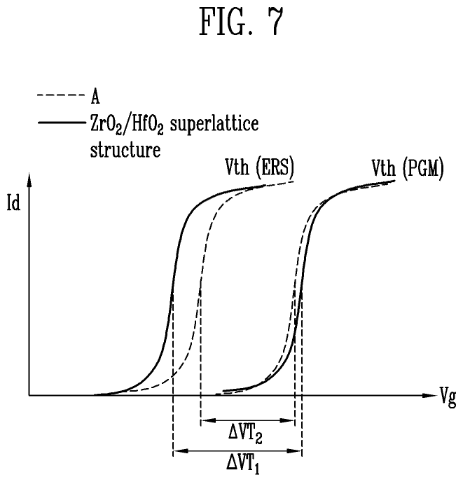

FIGS. 5 and 6 are diagrams illustrating an erase operation of a semiconductor memory device according to an embodiment of the present disclosure.

FIG. 5 is an energy band diagram illustrating an erase operation. As shown in FIG. 5, the bottom edge of the conduction band is denoted by Ec, and the top edge of the valence band is denoted by Ev. FIG. 6 shows saturation characteristics of an erase threshold voltage Vt according to an erase bias applied during an erase operation.

Referring to FIG. 5, the thickness of each of the tunnel insulating layer TI, the data storage layer DS, and the blocking insulating layer BI disposed between the channel layer CH and the word line WL and band offsets therebetween are mere examples and may vary depending on the material.

In FIGS. 5 and 6, the blocking insulating layer BI having the ZrO₂/HfO₂ superlattice structure is indicated by a solid line and the blocking insulating layer configured as the control group “A” is indicated by a dotted line. The tunnel insulating layer TI including a silicon oxide is shown as an example, and the data storage layer DS including a charge trap layer formed of a silicon nitride is shown as an example.

Referring to FIG. 5, during an erase operation, a high-voltage erase bias may be applied to the channel layer CH and an electric field may be applied to each of the tunnel insulating layer TI, the data storage layer DS, and the blocking insulating layer BI. During the erase operation, holes (h+) may tunnel through the tunnel insulating layer TI from the channel layer CH and be injected into data storage layer DS. Accordingly, the threshold voltage of the memory cell MC may decrease and be in an erase state. During the erase operation, electrons (e−) from the word line WL may tunnel through the blocking insulating layer BI due to the electric field applied to the blocking insulating layer BI. As a result, a back tunneling current may occur.

The back tunneling current may depend on a tunneling length of the electron (e−) and the tunneling length may increase when the dielectric constant becomes higher. The blocking insulating layer BI having the ZrO₂/HfO₂ superlattice structure may have a higher dielectric constant than the blocking insulating layer configured as the control group “A”. Accordingly, during the erase operation, the tunneling length of the electron (e-) may be greater in the blocking insulating layer BI having the ZrO₂/HfO₂ superlattice structure than in the blocking insulating layer configured as the control group “A”, so that the back tunneling current may decrease in the blocking insulating layer BI having the ZrO₂/HfO₂ superlattice structure. As a result, the erase speed of the memory cell including the blocking insulating layer BI having the ZrO₂/HfO₂ superlattice structure may be increased.

Referring to FIG. 6, in the blocking insulating layer configured as the control group “A”, the threshold voltage of a memory cell may decrease as the erase bias increases due to the back tunneling current. However, after a saturation point P1, an erase saturation phenomenon may occur in which the threshold voltage value might not decrease but may increase even when the erase bias increases. In contrast, in an embodiment, the erase saturation phenomenon may be improved as the back tunneling current decreases in the blocking insulating layer BI having the ZrO₂/HfO₂ superlattice structure.

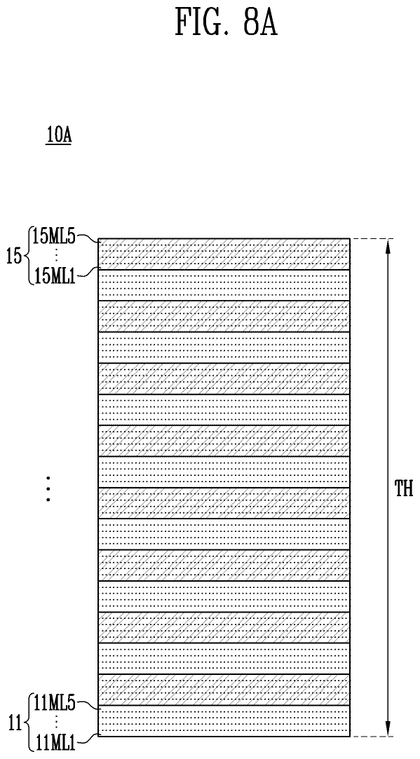

FIG. 7 is a graph for illustrating current-voltage characteristics of a program state PGM and an erase state ERS on a memory cell according to an embodiment of the present disclosure.

Referring to FIG. 7, the program state PGM and the erase state ERS on the memory cell, which includes the blocking insulating layer BI having the ZrO₂/HfO₂ superlattice structure, are indicated by solid lines, and the program state PGM and the erase state ERS on the memory cell, which includes the blocking insulating layer configured as the control group “A”, are indicated by dotted lines.

A threshold voltage variation AVTi of the program state PGM and the erase state ERS of the memory cell, which includes the blocking insulating layer BI having the ZrO₂/HfO₂ superlattice structure, may be greater than a threshold voltage variation ΔVT₂ of the program state PGM and the erase state ERS of the memory cell, which includes the blocking insulating layer configured as the control group “A”. As a result, it will be understood that a memory window of a memory cell including a blocking insulating layer having a superlattice structure is increased. Accordingly, a semiconductor memory device including the blocking insulating layer BI having the ZrO₂/HfO₂ superlattice structure may secure a threshold voltage distribution margin of a multi-level cell, such as a triple-level cell TLC or a quad-level cell QLC.

Referring to a current Id with respect to a gate voltage Vg applied to the word line WL, it may be seen that a program speed of the memory cell including the blocking insulating layer BI having the ZrO₂/HfO₂ superlattice structure is enhanced more than a program speed of the memory cell including the blocking insulating layer configured as the control group “A”. During a program operation, an electric field, which is applied to the tunnel insulating layer TI at the same gate voltage Vg, may be greater in the memory cell including the blocking insulating layer BI having the ZrO₂/HfO₂ superlattice structure than in the memory cell including the blocking insulating layer configured as the control group “A”. Therefore, the charge trapping speed in the data storage layer DS may be increased. Accordingly, in an embodiment, the program efficiency of the memory cell having the superlattice structure may be improved.

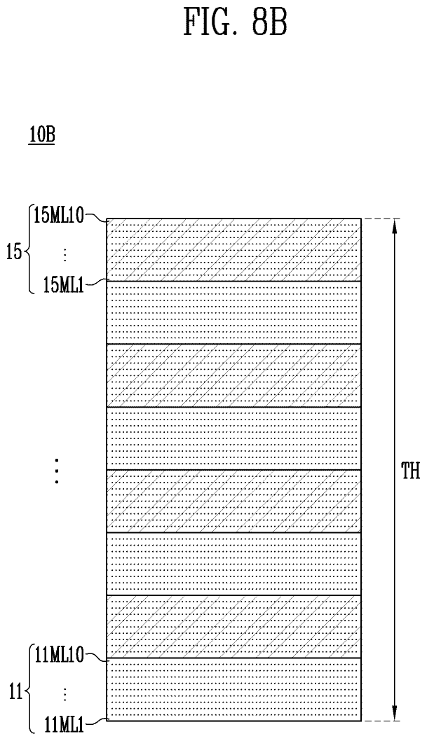

FIGS. 8A and 8B are cross-sectional views illustrating superlattice structures 10A and 10B according to embodiments of the present disclosure.

Referring to FIGS. 8A and 8B, a dielectric constant of the superlattice structure 10A or 10B may be controlled differently in a range of two to six times as much as the single hafnium oxide (HfO₂) layer, two to six times as much as the single zirconium oxide (ZrO₂) layer, or 10 to 30 times as much as the single silicon oxide (SiO₂) layer according to repeating cycles of monomolecular layers of the first dielectric layer 11 and the second dielectric layer 15 based on the same thickness TH.

In an embodiment, referring to FIG. 8A, the thickness TH of the superlattice structure 10A may be defined by the alternately stacked structure of the first dielectric layer 11 including first to fifth monomolecular layers 11ML1 to 11ML5 formed in a growth direction and the second dielectric layer 15 including first to fifth monomolecular layers 15ML1 to 15ML5 formed in the growth direction.

In an embodiment, referring to FIG. 8B, the thickness TH of the superlattice structure 10B may be defined by the alternately stacked structure of the first dielectric layer 11 including first to tenth monomolecular layers 11ML1 to 11ML10 formed in a growth direction and the second dielectric layer 15 including first to tenth monomolecular layers 15ML1 to 15ML10 formed in the growth direction.

Referring to FIGS. 8A and 8B, the dielectric constant may be controlled according to the numbers of monomolecular layers constituting the first dielectric layer 11 and the second dielectric layer 15. In an embodiment, when the number of monomolecular layers constituting each of the first dielectric layer 11 and the second dielectric layer 15 decreases, the dielectric constant may increase. The numbers of monomolecular layers constituting the first dielectric layer 11 and the second dielectric layer 15 are not limited to those shown in FIGS. 8A and 8B and may be changed. In an embodiment, at least one of the first dielectric layers 11 may have a different number of monomolecular layers than at least one of the second dielectric layers 15.

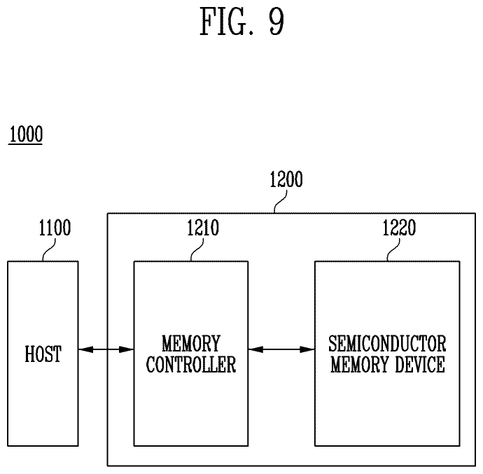

FIG. 9 is a block diagram illustrating an electronic system 1000 according to an embodiment of the present disclosure.

Referring to FIG. 9, the electronic system 1000 may be a computing system, a medical device, a communication device, a wearable device, a memory system, or the like. The electronic system 1000 may include a host 1100 and a storage device 1200.

The host 1100 may store data in the storage device 1200 or may read data stored in the storage device 1200 based on an interface. The interface may include at least one of interfaces such as Double Data Rate (DDR), Universal Serial Bus (USB), Multi-Media Card (MMC), embedded MMC (eMMC), Peripheral Component Interconnection (PCI), PCI-express (PCI-E), Advanced Technology Attachment (ATA), Serial-ATA (SATA), Parallel-ATA (PATA), Small Computer System Interface (SCSI), Enhanced Small Disk Interface (ESDI), an integrated drive electronics (IDE), Firewire, Universal flash storage (UFS), and NVMe interfaces.

The storage device 1200 may include a memory controller 1210 and a semiconductor memory device 1220. In an embodiment, the storage device 1200 may be a solid state drive (SSD) or a universal serial bus (USB) memory.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output stored data under the control of the memory controller 1210.

The semiconductor memory device 1220 may include NAND flash memory cells. A NAND flash memory cell may include a blocking insulating layer having a superlattice structure. According to an embodiment of the present disclosure, a dielectric constant of a blocking insulating layer may be increased by using a superlattice structure, thereby improving the operational reliability of a semiconductor memory device.

What is claimed is:

1. A semiconductor memory device, comprising:
a data storage layer;
a word line overlapping with the data storage layer; and
a blocking insulating layer interposed between the data storage layer and the word line, the blocking insulating layer comprising a superlattice structure.

2. The semiconductor memory device of claim 1, further comprising:
a channel layer overlapping with the word line, the blocking insulating layer and data storage layer interposed between the word line and the channel layer.

3. The semiconductor memory device of claim 1, further comprising:
a tunnel insulating layer overlapping with the word line, the blocking insulating layer and data storage layer interposed between the word line and the tunnel insulating layer.

4. The semiconductor memory device of claim 1, wherein the blocking insulating layer includes one or more pairs of dielectric layers, each pair of dielectric layers comprising a first dielectric layer and a second dielectric layer disposed in a direction from the data storage layer towards the word line.

5. The semiconductor memory device of claim 4, wherein each of the first dielectric layer and the second dielectric layer includes a crystalline oxide.

6. The semiconductor memory device of claim 4, wherein one of the first dielectric layer and the second dielectric layer includes a ferroelectric material and the other includes an antiferroelectric material.

7. The semiconductor memory device of claim 4, wherein the first dielectric layer includes a different crystalline phase from the second dielectric layer.

8. The semiconductor memory device of claim 7, wherein one of the first dielectric layer and the second dielectric layer includes an orthorhombic crystalline phase and the other includes a tetragonal crystalline phase.

9. The semiconductor memory device of claim 4, wherein the first dielectric layer includes a different crystalline phase distribution from the second dielectric layer.

10. The semiconductor memory device of claim 9, wherein each of the first dielectric layer and the second dielectric layer includes an orthorhombic crystalline phase, a tetragonal crystalline phase, and a monoclinic crystalline phase, and
wherein one of the first dielectric layer and the second dielectric layer includes the orthorhombic crystalline phase more than the tetragonal crystalline phase and the monoclinic crystalline phase, and the other includes the tetragonal crystalline phase more than the orthorhombic crystalline phase and the monoclinic crystalline phase.

11. The semiconductor memory device of claim 4, wherein one of the first dielectric layer and the second dielectric layer includes a hafnium oxide (HfO₂) layer and the other includes a zirconium oxide (ZrO₂) layer.

12. The semiconductor memory device of claim 1,
wherein the blocking insulating layer includes first dielectric layers and second dielectric layers, the first dielectric layers alternately stacked with the second dielectric layers, and
wherein at least one of the first dielectric layers comprises a different number of monomolecular layers than at least one of the second dielectric layers.

13. A semiconductor memory device, comprising:
a plurality of word lines stacked separately from each other;
a channel layer extending in a stacking direction of the plurality of word lines to penetrate the plurality of word lines;
a blocking insulating layer interposed between the channel layer and each of the plurality of word lines, wherein the blocking insulating layer includes a superlattice structure;
a data storage layer interposed between the channel layer and the blocking insulating layer; and
a tunnel insulating layer interposed between the channel layer and the data storage layer.

14. The semiconductor memory device of claim 13, wherein the blocking insulating layer includes one or more pairs of dielectric layers, each pair of dielectric layers comprising a first dielectric layer and a second dielectric layer disposed in a direction from the data storage layer towards the plurality of the word lines.

15. The semiconductor memory device of claim 14, wherein each of the first dielectric layer and the second dielectric layer includes a crystalline oxide.

16. The semiconductor memory device of claim 14, wherein one of the first dielectric layer and the second dielectric layer includes a ferroelectric material and the other includes an antiferroelectric material.

17. The semiconductor memory device of claim 14, wherein the first dielectric layer includes a different crystalline phase from the second dielectric layer.

18. The semiconductor memory device of claim 17, wherein one of the first dielectric layer and the second dielectric layer includes an orthorhombic crystalline phase and the other includes a tetragonal crystalline phase.

19. The semiconductor memory device of claim 14, wherein the first dielectric layer includes a different crystalline phase distribution from the second dielectric layer.

20. The semiconductor memory device of claim 19, wherein each of the first dielectric layer and the second dielectric layer includes an orthorhombic crystalline phase, a tetragonal crystalline phase, and a monoclinic crystalline phase, and
wherein one of the first dielectric layer and the second dielectric layer includes the orthorhombic crystalline phase more than the tetragonal crystalline phase and the monoclinic crystalline phase, and the other includes the tetragonal crystalline phase more than orthorhombic crystalline phase and the monoclinic crystalline phase.

21. The semiconductor memory device of claim 14, wherein one of the first dielectric layer and the second dielectric layer includes a hafnium oxide (HfO₂) layer and the other includes a zirconium oxide (ZrO₂) layer.
